(19) United States
(12) Patent Application Publication
(10) Pub. No.: US 2020/0075593 A1
(43) Pub. Date: Mar. 5, 2020

(54) SEMICONDUCTOR DEVICE AND MANUFACTURING METHOD THEROF

(71) Applicant: SiEn (QingDao) Integrated Circuits Co., Ltd, Qingdao (CN)

(72) Inventor: Deyuan Xiao, Shanghai (CN)

(21) Appl. No.: 16/555,939

(22) Filed: Aug. 29, 2019

(30) Foreign Application Priority Data
Sep. 3, 2018 (CN) 201811023031.3

(51) Int. Cl. H01L 27/092; H01L 29/423; H01L 29/778; H01L 29/78; H01L 21/8238

(52) U.S. Cl. CPC H01L 27/0922; H01L 29/42392; H01L 21/823807; H01L 29/7842; H01L 29/7854; H01L 29/7786

(57) ABSTRACT

This invention provides a semiconductor device and a manufacturing method thereof. The semiconductor device comprises a subtract; a semiconductor channel, hanging on the subtract; a first semiconductor layer, wrapped all around the semiconductor channel; a second semiconductor layer, wrapped all around the first semiconductor layer; a gate dielectric layer, wrapped all around the second semiconductor layer; and a gate electrode layer, wrapped all around the gate dielectric layer, wherein the first semiconductor layer includes a smaller bandgap than a bandgap of the semiconductor channel. The present inventor includes a quantum well of two dimensional hole gas and a quantum well of two dimensional electron gas, that can improve the electron mobility transistor of holes and electrons, improve the current carrying capacity of N-type Field-Effect Transistor and P-type Field-Effect Transistor, and reduce the resistance and the power consumption.

### CROSS-REFERENCE TO RELATED APPLICATIONS

This application claims priority to P.R.C. Patent Application No. 201811023031.3 titled “semiconductor device and manufacturing method thereof,” filed on Sep. 3, 2018, with the State Intellectual Property Office of the People's Republic of China (SIPO).

### TECHNICAL FIELD

The present disclosure relates to the design and manufacture of integrated circuits, and particularly, to a three-dimensional stacked quantum well complementary semiconductor device structure and a method for manufacturing the same.

### BACKGROUND

Fin field-effect transistor (FinFET) is a new complementary MOS transistor. The shape of the FinFET is similar to that of a fin. This design can improve circuit control, reduce leakage current and shorten the gate length of the transistor

FinFET is an innovative design of a transistor-Field Effect Transistor (FET) derived from the traditional standard. In a conventional transistor structure, the gate can only control the on and off of a current in a surface of the channel region, which is a planar structure. In the FinFET architecture, the gate is designed in a fin-shaped 3D architecture that can control the on and off of the circuit on either side of the finned gate. This design can greatly improve circuit control and reduce leakage, and can also significantly shorten the channel length of the transistor.

In early 2011, Intel introduced a commercial FinFET which is used on its 22 nm node process to provide faster and more power saving processors for future mobile processors, etc. In 2015, Samsung took the lead in using FinFET technology for 10 nm process. In 2016, TSMC also used FinFET technology for 10 nm process nodes.

As an improvement of the FinFET technology, the three-sided surrounding gate field effect transistor can effectively improve the power and efficiency of the field effect transistor, which has only recently begun to be used in the fields of server, computers and equipment, such that the three-sided surrounding gate field effect transistor will be the mainstream technology for the next few years.

As the demand for integration level, power, and performance of the device are further improved, power and performance can be further improved by stacking silicon nanosheets together. In U.S. Pat. No. 8,350,298, Xiao Deyuan et al. propose a hybrid crystal orientation inversion-mode type full-encapsulation gate CMOS field effect transistor, as shown in FIG. 1, which comprises: a bottom semiconductor substrate 100, a PMOS region having a first channel 401, a NMOS region having a second channel 301, and a gate region 500 having a gate dielectric layer 501. The cross sections of the first channel 401 and the second channel 301 are all racetrack shapes. The gate dielectric layer 501 of the gate region 500 completely are wrapped around the surfaces of the first channel 401 and the second channel 301. A second buried oxide layer 202 is disposed between the NMOS region 300 and the underlying semiconductor substrate 100 (i.e. Si substrate). A gate electrode material layer 502 substantially surrounding the gate dielectric layer 501. This device can avoid polycrystalline silicon gate depletion and short channel effects, and increasing the threshold voltage of the device. However, this device has a large limitation on the channel electron mobility, and the device still cannot fully meet the demand for further improvement in power and performance.

Based on the above, it is necessary to provide a semiconductor device structure that can improve the power and performance of the device.

### SUMMARY

In light of the abovementioned problems, an object of the present disclosure is to provide a semiconductor device and a manufacturing method thereof, which can solve the problem of low carrier mobility of the device in the prior art.

An objective of the present invention is to provide a semiconductor device. The semiconductor device may comprise a subtract; a semiconductor channel, suspended above the subtract; a first semiconductor layer, wrapped all around the semiconductor channel; a second semiconductor layer, wrapped all around the first semiconductor layer; a gate dielectric layer, wrapped all around the second semiconductor layer; and a gate electrode layer, wrapped all around the gate dielectric layer, in which the first semiconductor layer has a band gap narrower than a band gap of the semiconductor channel.

In accordance with some embodiments, the first semiconductor layer comprises a quantum well layer, and a two-dimensional hole gas is formed in the quantum well layer.

In accordance with some embodiments, the material of the semiconductor channel includes Si, and the material of the first semiconductor layer includes Ge.

In accordance with some embodiments, the material of the first semiconductor layer includes one of Ge and SiGe having compressive strain, in which the content of Ge in SiGe is at least 50%.

In accordance with some embodiments, the second semiconductor layer has a band gap wider than a band gap of the first semiconductor and narrower than a band gap of the semiconductor channel.

In accordance with some embodiments, the second semiconductor layer comprises a quantum well layer, and a two-dimensional electron gas is formed in the quantum well layer.

In accordance with some embodiments, the material of the first semiconductor layer includes Ge, and the material of the second semiconductor layer includes Si.

In accordance with some embodiments, the material of the first semiconductor layer includes one of Ge and SiGe having compressive strain, in which the content of Ge in SiGe is at least 50%, and the material of the second semiconductor layer includes Si having compressive strain.

In accordance with some embodiments, the semiconductor channel is rounded to have a cross-sectional shape of a rounded rectangle.

In accordance with some embodiments, the semiconductor device includes at least two of the semiconductor channels, a P-type field effect transistor is formed based on a first semiconductor channel, an N-type field effect transistor is formed based on a second semiconductor channel, and a gate electrode layer of the N-type field effect transistor is connected with a gate electrode layer of the P-type field effect transistor by a common electrode to form an inverter.

In accordance with some embodiments, the semiconductor device includes at least two N-type field effect transistors stacked upward from the substrate and at least two P-type field effect transistors stacked upward from the substrate, and there is a gap between two adjacent N-type field effect transistors and a gap between two adjacent P-type field effect transistors.

In accordance with some embodiments, the material of the gate electrode layer of the N-type field effect transistor includes one of TiN, TaN, TiAl, and Ti, the material of the gate electrode layer of the P-type field effect transistor includes one of TiN, TaN, TiAl, and Ti, and the material of the common electrode includes one of Al, W, and Cu.

Another objective of the present invention is to provide a manufacturing method of a semiconductor device. The manufacturing method of the semiconductor device comprises the steps of: 1) providing a subtract with a semiconductor channel suspended above the subtract; 2) forming a first semiconductor layer wrapped all around the semiconductor channel with a band gap of the first semiconductor layer narrower than a band gap of the semiconductor channel; 3) forming a second semiconductor layer wrapped all around the first semiconductor layer; 4) forming a gate dielectric layer wrapped all around the second semiconductor layer; and 5) forming a gate electrode layer wrapped all around the gate dielectric layer.

In accordance with some embodiments, the first semiconductor layer comprises a quantum well layer, and a two-dimensional hole gas is formed in the quantum well layer.

In accordance with some embodiments, the material of the semiconductor channel includes Si, and the material of the first semiconductor layer includes Ge.

In accordance with some embodiments, the material of the first semiconductor layer includes one of Ge and SiGe having compressive strain, in which the content of Ge in SiGe is at least 50%.

In accordance with some embodiments, the second semiconductor layer has a band gap wider than a band gap of the first semiconductor and narrower than a band gap of the semiconductor channel.

In accordance with some embodiments, the second semiconductor layer comprises a quantum well layer, and a two-dimensional electron gas is formed in the quantum well layer.

In accordance with some embodiments, the material of the first semiconductor layer includes Ge, and the material of the second semiconductor layer includes Si.

In accordance with some embodiments, the material of the first semiconductor layer includes one of Ge and SiGe having compressive strain, in which the content of Ge in SiGe is at least 50%, and the material of the second semiconductor layer includes Si having compressive strain.

In accordance with some embodiments, the step 1) further comprises a step of rounding the semiconductor channel such that the semiconductor channel has a cross-sectional shape of a rounded rectangle.

In accordance with some embodiments, the step 1) comprises a step of forming at least two of the semiconductor channels on the substrate, and the method further comprises steps of forming a P-type field effect transistor based on a first semiconductor channel, forming an N-type field effect transistor based on a second semiconductor channel, and depositing a common electrode after the step 5), in which the common electrode connects a gate electrode layer of the N-type field effect transistor with a gate electrode layer of the P-type field effect transistor to form an inverter.

In accordance with some embodiments, the step 1) comprises a step of forming at least two first semiconductor channels stacked upward from the substrate and at least two second semiconductor channels stacked upward from the substrate, in which there is a gap between two adjacent first semiconductor channels and a gap between two adjacent second semiconductor channels, and the method further comprises steps of forming at least two P-type field effect transistors stacked upward from the substrate based on the first semiconductor channel, forming at least two N-type field effect transistors stacked upward from the substrate based on the second semiconductor channel, and depositing a common electrode after the step 5), in which the common electrode connects a gate electrode layer of the N-type field effect transistors with a gate electrode layer of the P-type field effect transistors to form an inverter.

In accordance with some embodiments, the material of the gate electrode layer of the N-type field effect transistors includes one of TiN, TaN, TiAl, and Ti, the material of the gate electrode layer of the P-type field effect transistors includes one of TiN, TaN, TiAl, and Ti, and the material of the common electrode includes one of Al, W, and Cu.

Another objective of the present invention is to provide a manufacturing method of a semiconductor device. The manufacturing method of the semiconductor device comprises the steps of: 1) providing a subtract with a plurality of body structure layers stacked above the subtract, in which each of the body structure layers includes a sacrifice layer and a channel layer on the sacrifice layer; 2) etching the pluralities of body structure layers to form a first fin structure and a second fm structure adjacent with each other, in which the first fm structure includes a plurality of first sacrificial units and a plurality of first semiconductor channels alternatively stacked, and the second fm structure includes a plurality of second sacrificial units and a plurality of second semiconductor channels alternatively stacked; 3) selectively removing the first sacrificial units in the first fin structure and the second sacrificial units in the second fin structure to obtain suspended first semiconductor channels and suspended second semiconductor channels; 4) forming a first semiconductor layer wrapped all around the first semiconductor channels and the second semiconductor channels, in which the first semiconductor layer has a band gap narrower than a band gap of the semiconductor channels; and 5) forming a second semiconductor layer wrapped all around the first semiconductor layer, in which the second semiconductor layer has a band gap wider than a band gap of the first semiconductor layer and narrower than a band gap of the semiconductor channels.

In accordance with some embodiments, the method further comprise steps: 6) forming a gate dielectric layer wrapped all around the second semiconductor layer; 7) forming a gate electrode layer wrapped all around the gate dielectric layer; and 8) forming a P-type field effect transistor based on the first semiconductor channel, forming an N-type field effect transistor based on the second semiconductor channel, in which a gate electrode layer of the N-type field effect transistor is connected with a gate electrode layer of the P-type field effect transistor by a common electrode to form an inverter.

In accordance with some embodiments, the first semiconductor layer comprises a quantum well layer, and a two-dimensional hole gas is formed in the quantum well layer.

In accordance with some embodiments, the material of the semiconductor channel includes Si, and the material of the first semiconductor channel includes one of Ge and SiGe having compressive strain, in which the content of Ge in SiGe is at least 50%.

In accordance with some embodiments, the second semiconductor layer comprises a quantum well layer, and a two-dimensional electron gas is formed in the quantum well layer.

In accordance with some embodiments, the material of the first semiconductor channel includes one of Ge and SiGe having compressive strain, in which the content of Ge in SiGe is at least 50%, and the material of the second semiconductor layer includes Si having compressive strain.

As described above, the semiconductor device and the manufacturing method thereof have the following beneficial effects:

At least one of the above and other features and advantages of the present invention may be realized by providing a three-dimensional stacked gate-all-around field effect transistor structure, which can realize multi-layer stack of device under a unit area, effectively improve the integration level of device, and greatly improve the power of device.

The present invention has an ability to greatly improve the mobility of holes, improve the current carrying capacity of the P-type field effect transistor, and reduce the resistance and power consumption by wrapping a layer of first semiconductor layer around a silicon nano channel, such as Ge, to make the first semiconductor layer have a band gap narrower than a band gap of the semiconductor channel to form a two-dimension hole gas in the quantum well. Further, the present invention has an ability to greatly improve the mobility of electrons, improve the current carrying capacity of the N-type field effect transistor, and reduce the resistance and power consumption by wrapping a layer of second semiconductor layer around the first semiconductor layer, such as Si, to make the second semiconductor layer have a band gap wider than a band gap of the first semiconductor layer to form a two-dimension electron gas in the quantum well.

### BRIEF DESCRIPTION OF THE DRAWINGS

Exemplary embodiments will be more readily understood from the following detailed description when read in conjunction with the appended drawings, in which:

FIG. 1 depicts a schematic view of a mixed crystal orientation accumulation type gate-all-around CMOS field effect transistor in the prior art;

FIG. 2 depicts a schematic view of a three-dimensional stacked quantum well complementary semiconductor device according to some embodiments of the present disclosure;

FIG. 3 depicts a schematic circuit diagram of the three-dimensional stacked quantum well complementary semiconductor device with the N-type field effect transistor connected with the P-type field effect transistor by a common electrode according to some embodiments of the present disclosure;

FIG. 4 depicts a band gap diagram of the three-dimensional stacked quantum well complementary semiconductor device according to some embodiments of the present disclosure;

FIGS. 5-14 depict various stages of sequential manufacturing process of the three-dimensional stacked quantum well complementary semiconductor device according to some embodiments of the present disclosure.

### DETAILED DESCRIPTION

The embodiments of the present invention are described below by way of specific examples, and those skilled in the art can readily understand other advantages and effects of the present invention from the disclosure of the present disclosure. The present invention may be embodied or applied in various other specific embodiments, and various modifications and changes can be made without departing from the spirit and scope of the invention.

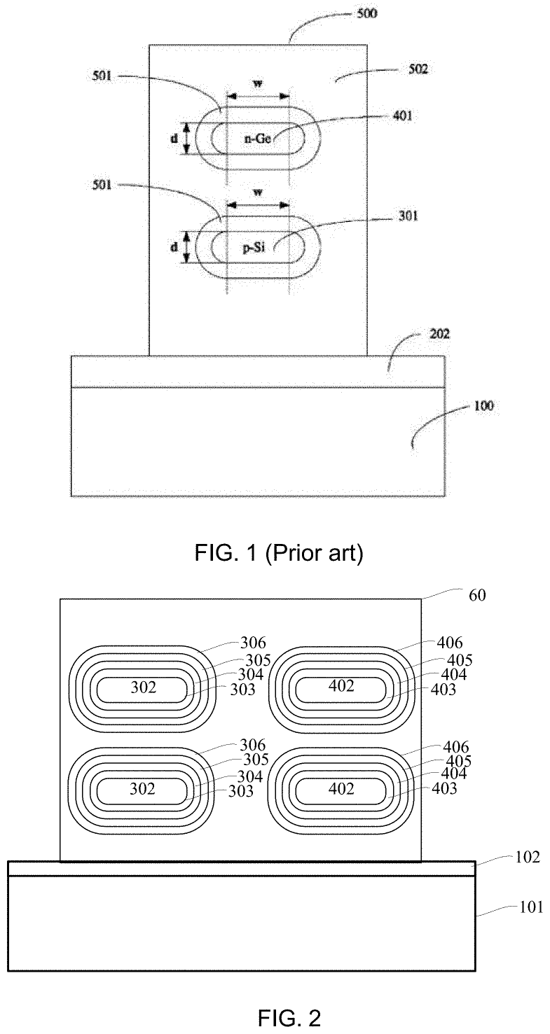

Referring to FIGS. 2 through 14. It should be noted that the illustrations provided in this embodiment merely illustrate the basic concept of the present invention in a schematic manner, and only the components related to the present invention are shown in the drawings, instead of the number and shape of components in actual implementation. Dimensional drawing, the actual type of implementation of each component type, number and proportion can be a random change, and its component layout can be more complicated.

As shown in FIG. 2, the present disclosure provides a three-dimensional stacked quantum well complementary semiconductor device, which comprises: a substrate 101, a semiconductor channel, first semiconductor layers 303, 403, second semiconductor layers 304, 404, gate dielectric layers 305, 405, and gate electrode layers 306, 406.

The substrate 101 may be a silicon (Si) substrate, a silicon carbide substrate 101, a silicon germanium (SiGe) substrate 101, etc. In this embodiment, the substrate 101 is a silicon substrate 101, in which an insulator layer 102 is formed on a surface of the silicon substrate 101 to insulate the substrate 101 from a drain region and a sequentially formed common electrode 60 of the device for improving the performance of the device.

As shown in FIG. 2, the semiconductor channel is suspended over the substrate 101. The semiconductor channel can be rounded to have a cross-sectional shape of a rounded rectangle. The material of the semiconductor channel may be silicon. In this embodiment, the semiconductor device can include two first semiconductor channels 302 stacked upward from the substrate 101 and two second semiconductor channels 402 stacked upward from the substrate 101, in which the first semiconductor channels 302 can be configured to be P-type field effect transistors, and the second semiconductor channels 402 can be configured to be N-type field effect transistors.

As shown in FIG. 2, the first semiconductor layers 303, 403 can be wrapped all around the semiconductor channel with a band gap of the first semiconductor layers 303, 403 narrower than a band gap of the semiconductor channel, such that the first semiconductor layers 303, 403 can include a quantum well layer 501, in which a two-dimensional hole gas can be formed in the quantum well layer 501. The material of the first semiconductor layers 303, 403 can include Ge. For example, the material of the first semiconductor layers 303, 403 can include one of Ge and SiGe having compressive strain, in which the content of Ge in SiGe may be at least 50%. For example, the content of Ge in SiGe is 50%, 60%, 75%, 85%, etc. By adjusting the content of Ge in the SiGe, the lattice constant, strain degree, band gap width, and hole mobility can be adjusted to meet actual production requirements.

As shown in FIG. 2, the second semiconductor layers 304, 404 can be wrapped all around the first semiconductor layers 303, 403. A band gap of the second semiconductor layers 304, 404 may be wider than a band gap of the first semiconductor layers 303, 403, and the band gap of the second semiconductor layers 304, 404 may be narrower than the band gap of the semiconductor channel, such that the second semiconductor layers 304, 404 can include a quantum well layer 502, in which a two-dimensional electron gas can be formed in the quantum well layer 502.

The material of the second semiconductor layers 304, 404 can include Si. For example, the material of the second semiconductor layers 304, 404 can be Si having compressive strain.

As shown in FIG. 2, the gate dielectric layers 305, 405 can be wrapped all around the second semiconductor layers 304, 404. The material of the gate dielectric layers 305, 405 may be one of high dielectric constant materials, such as silicon dioxide, aluminum oxide, nitride-oxide-silicon compound, silicon-carbon-oxide compound or hafnium base.

The gate electrode layers 306, 406 can be wrapped all around the gate dielectric layers 305, 405. The gate electrode layers 306, 406 may include the gate electrode layers 306 of P-type field effect transistors and the gate electrode layers 406 of N-type field effect transistors. The gate electrode layers 306 of P-type field effect transistors may be disposed corresponding to the first semiconductor channels 302. The gate electrode layers 406 of N-type field effect transistors may be disposed corresponding to the second semiconductor channels 402.

The material of the gate electrode layers 406 of N-type field effect transistors may include one of TiN, TaN, TiAl and Ti.

The material of the gate electrode layers 306 of P-type field effect transistors may include one of TiN, TaN, TiAl and Ti.

For example, the material of the gate electrode layers 406 of N-type field effect transistors may be different from the material of the gate electrode layers 306 of P-type field effect transistors.

As shown in FIG. 2, the P-type field effect transistor may be composed of the first semiconductor channel 302 and the first semiconductor layers 303, the second semiconductor layers 304, the gate dielectric layer 305, and the gate electrode layers 306 sequentially wrapped all around the first semiconductor channel 302. The N-type field effect transistor may be composed of the second semiconductor channel 402 and the first semiconductor layers 403, the second semiconductor layers 404, the gate dielectric layer 405, and the gate electrode layers 406 sequentially wrapped all around the second semiconductor channel 402. The semiconductor device may include at least two N-type field effect transistors stacked upward from the substrate 101 and at least two P-type field effect transistors stacked upward from the substrate 101, and there is a gap between two adjacent N-type field effect transistors and a gap between two adjacent P-type field effect transistors. The gate electrode layers 406 of the N-type field effect transistor may be connected with the gate electrode layers 306 of the P-type field effect transistor by a common electrode 60 to form an inverter, in which the material of the common electrode 60 may include one of Al, W, and Cu.

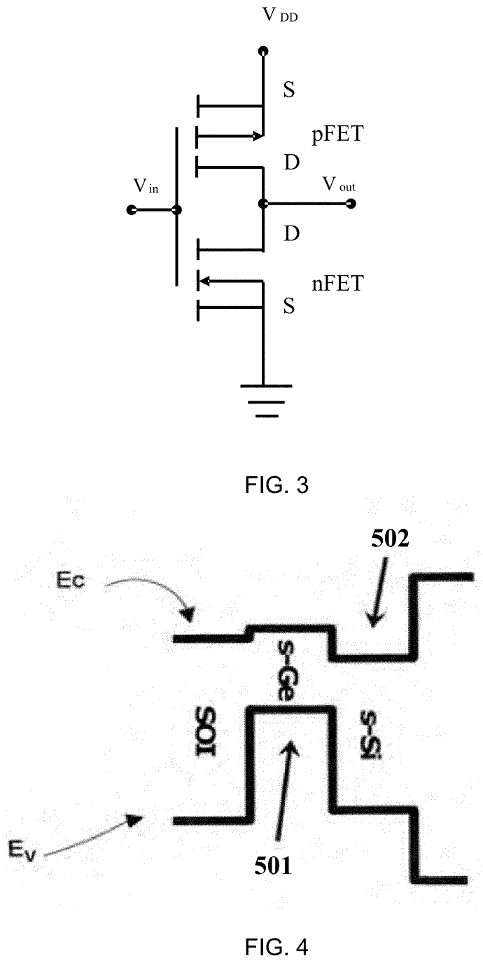

FIG. 3 depicts a schematic circuit diagram of the N-type field effect transistor connected with the P-type field effect transistor by the common electrode 60 according to some embodiments of the present disclosure. The gate electrode layers 406 of the N-type field effect transistor may be connected with the gate electrode layers of the P-type field effect transistor as an input terminal Vin. The source of the P-type field effect transistor may be connected with power source VDD. The drain of the N-type field effect transistor may be connected with the drain of the P-type field effect transistor as an output terminal Vout. The source of the N-type field effect transistor may be grounded.

FIG. 4 depicts a band gap diagram of the N-type field effect transistor or the P-type field effect transistor according to some embodiments of the present disclosure. The semiconductor channels may be silicon layers. The first semiconductor layers 303, 403 may be Ge layers having compressive strain. The second semiconductor layers 304, 404 may be Si layers having compressive strain. As shown in FIG. 4, taking the gate dielectric layers 305, 405 as silicon dioxide layers as an example, the valence band energy Ev and the conduction band energy Ec of the Ge layers may be both higher than the valence band energy Ev and the conduction band energy Ec of the Si layers, and higher than the valence band energy Ev and the conduction band energy Ec of the Si layers having compressive strain to form a quantum well with a two-dimensional hole gas in the Ge layers, such that the mobility of holes may be increased greatly. The conduction band energy Ec of the Si layers having compressive strain may be lower than the conduction band energy Ec of the Ge layers and the conduction band energy of the silicon dioxide layers to form a quantum well with a two-dimensional electron gas in the Si layers having compressive strain, such that the mobility of electrons may be increased greatly.

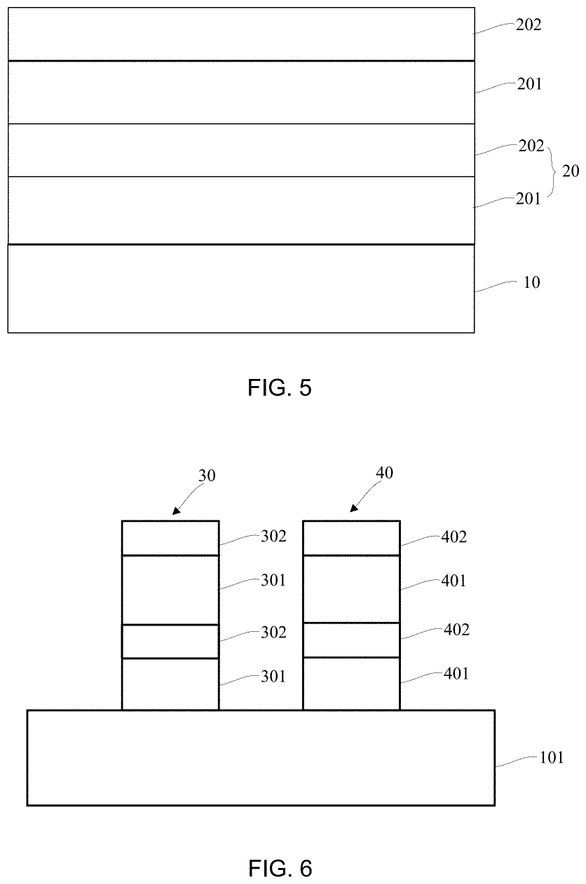

As shown in FIGS. 5 through 14, the present disclosure provides a manufacturing method of a three-dimensional stacked quantum well complementary semiconductor device. The manufacturing method may include the steps of:

As shown in FIGS. 5, step 1) is first performed, a subtract 101 with a plurality of substrate structure layers 20 stacked above the subtract 101, in which each of the substrate structure layers 20 may include a sacrifice layer 201 and a channel layer 202 on the sacrifice layer 201.

The substrate 101 may be a Si substrate, a silicon carbide substrate 101, a silicon germanium (SiGe) substrate 101, etc. In this embodiment, the substrate 101 is a silicon substrate 101. Then, the sacrificial layer 201 and the channel layer 202 are repeatedly formed on the substrate 101 by a process such as chemical vapor deposition. The material of the sacrificial layer 201 may be a silicon dioxide, and the material of the channel layer 202 may be silicon.

In this embodiment, the range of the thickness of the sacrificial layer 201 may be between 10˜200 nm, such as 50 nm, 100 nm, or 150 nm, and the range of the thickness of the channel layer 202 may be between 10˜100 nm, such as 25 nm, 50 nm, or 75 nm.

As shown in FIG. 6, step 2) is performed, the pluralities of substrate structure layers 20 are etched by a photolithography process and an etching process to form a first fin structure 30 and a second fm structure 40 adjacent with each other on the substrate 101, in which the first fin structure 30 may include a plurality of first sacrificial units 301 and a plurality of first semiconductor channels 302 alternatively stacked, and the second fin structure 40 may include a plurality of second sacrificial units 401 and a plurality of second semiconductor channels 402 alternatively stacked. The first sacrificial units 301 and the second sacrificial units 401 may be formed by etching the sacrificial layer 201, and the first semiconductor channels 302 and the second semiconductor channels 402 may be formed by etching the channel layer 202.

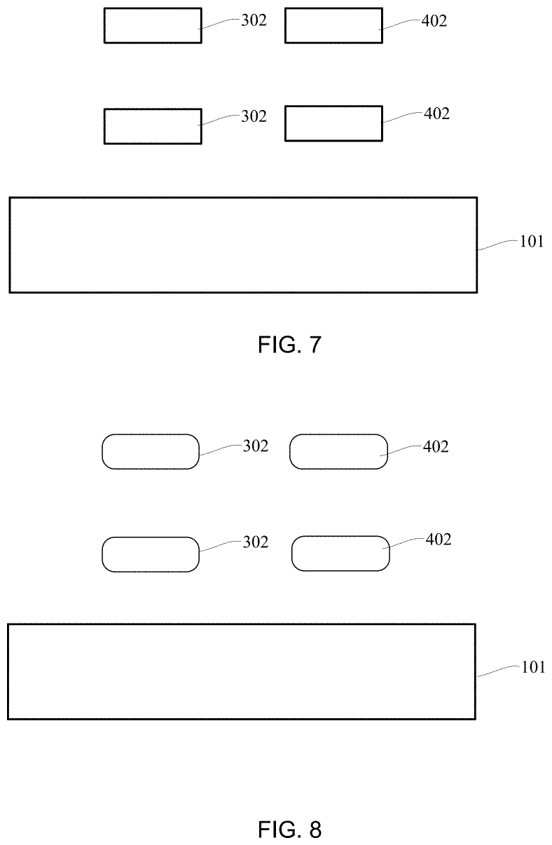

As shown in FIG. 7, step 3) is performed, the first sacrificial units 301 in the first fin structure 30 and the second sacrificial units 401 in the second fin structure 40 are selectively removed to obtain suspended first semiconductor channels 302 and suspended second semiconductor channels 402.

More specifically, the first sacrificial units 301 in the first fin structure 30 and the second sacrificial units 401 in the second fin structure 40 are wet etched by using a dilute hydrofluoric acid solution DHF to selectively remove the first sacrificial units 301 in the first fin structure 30 and the second sacrificial units 401 in the second fin structure 40 and to obtain the suspended first semiconductor channels 302 and the suspended second semiconductor channels 402.

As shown in FIG. 8, the semiconductor channels are rounded to have a cross-sectional shape of a rounded rectangle. More specifically, the rounded process may include: a) the first semiconductor channels 302 and the second semiconductor channels 402 may be oxidized by a thermal oxidation process to obtain thermal oxide layers wrapped all around the first semiconductor channels 302 and the second semiconductor channels 402, in which the oxidation temperature of the thermal oxidation process may be between 800° C. and 1200° C., and the oxidation period may be between 5 minutes and 8 hours; b) the thermal oxide layers may be wet etched using a dilute hydrofluoric acid solution DHF to remove it to obtain the first semiconductor channels 302 and the second semiconductor channels 402 having a rounded rectangular (or racetrack shape) cross-sectional shape.

In this embodiment, the semiconductor device can include two first semiconductor channels 302 stacked upward from the substrate 101 and two second semiconductor channels 402 stacked upward from the substrate 101, in which the first semiconductor channels 302 can be configured to be P-type field effect transistors, and the second semiconductor channels 402 can be configured to be N-type field effect transistors.

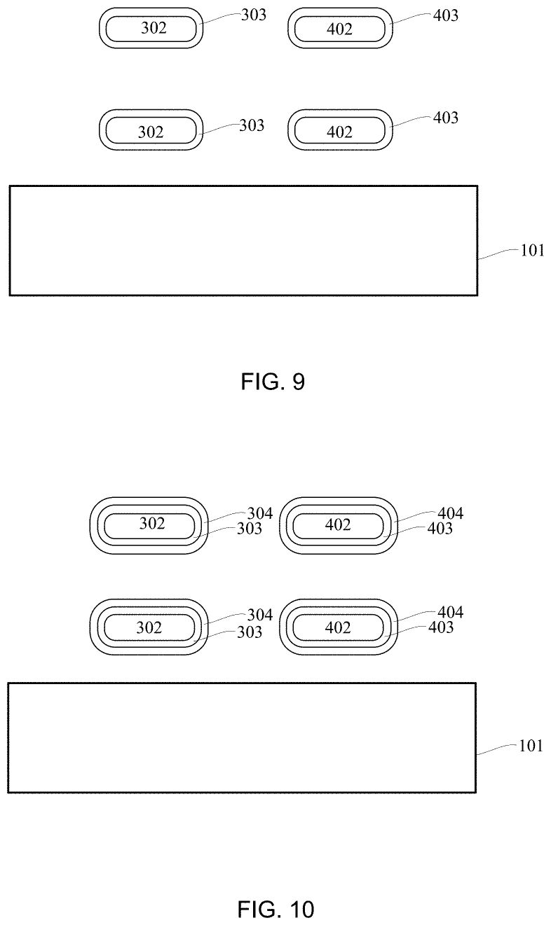

As shown in FIG. 9, step 4) is performed, first semiconductor layers 303, 403 are formed to be wrapped all around the first semiconductor channels 302 and the second semiconductor channels 402, in which the first semiconductor layers 303, 403 may have a band gap narrower than a band gap of any one of the semiconductor channels 302, 402.

For example, the first semiconductor layers 303, 403 wrapped all around the first semiconductor channels 302 and the second semiconductor channels 402 may be formed by using a chemical vapor deposition process (CVD) or an atomic layer deposition process (ALD), in which the first semiconductor layers 303, 403 may have a band gap narrower than a band gap of the first semiconductor channels 302 and a band gap of the second semiconductor channels 402 to form a quantum well with a two-dimensional hole gas in the first semiconductor layers 303, 403. The material of the first semiconductor layers 303, 403 may include Ge. For example, the material of the first semiconductor layers 303, 403 may be one of Ge and SiGe having compressive strain, in which the content of Ge in SiGe may be at least 50%. For example, the content of Ge in SiGe may be 50%, 60%, 75%, and 74%. By adjusting the content of Ge in the SiGe, the lattice constant, strain degree, band gap width, and holes mobility can be adjusted to meet actual production requirements. At the same time, the content of Ge in SiGe can also adjust the degree of strain of the subsequently deposited Si having tensile strain.

As shown in FIG. 10, step 5) is performed. Second semiconductor layers 304, 404 are formed to be wrapped all around the first semiconductor layers 303, 403, in which the second semiconductor layers 304, 404 may have a band gap wider than a band gap of the first semiconductor layers 303, 403 and narrower than a band gap of any one of the semiconductor channels 302, 402 to form a quantum well with a two-dimensional electron gas in the second semiconductor layers 304, 404.

For example, the second semiconductor layers 304, 404 wrapped all around the first semiconductor layers 303, 403 may be formed by using a chemical vapor deposition process (CVD) or an atomic layer deposition process (ALD), in which the material of the second semiconductor layers 304, 404 may include Si. For example, the material of the second semiconductor layers 304, 404 may be Si having compressive strain.

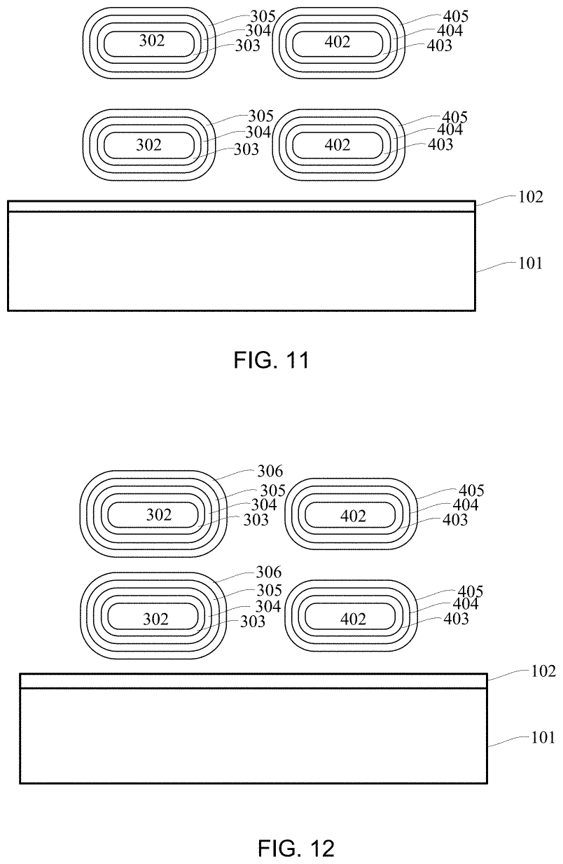

As shown in FIG. 11, step 6) is performed. Gate dielectric layers 305, 405 are formed to be wrapped all around the second semiconductor layers 304, 404. The material of gate dielectric layers 305, 405 may be one of high dielectric constant materials, such as silicon dioxide, aluminum oxide, nitride-oxide-silicon compound, silicon-carbon-oxide compound or hafnium base.

While forming the gate dielectric layers 305, 405, an isolation layer 102 may be formed on the surface of the substrate 101 to isolate the substrate 101 from the source region of the device and the subsequently formed common electrode 60, thereby improving the performance of components.

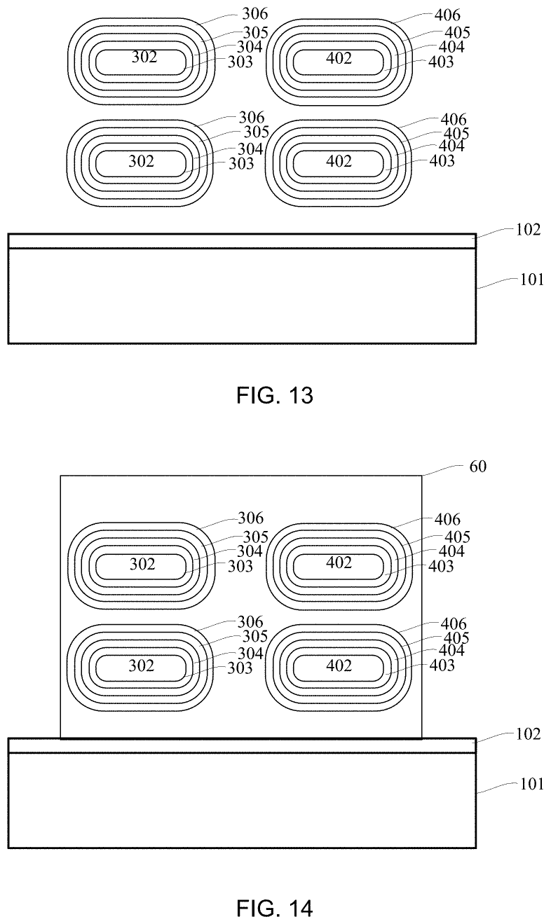

As shown in FIGS. 12 through 13, step 7) is performed. Gate electrode layers 306, 406 are formed to be wrapped all around the gate dielectric layers 305, 405. The step 7) may comprise following steps:

As shown in FIG. 12, step 7-1) is performed. Electron material layers may be deposited by using a chemical vapor deposition process (CVD) or an atomic layer deposition process (ALD), and then only the gate electrode layers 306 outside the first semiconductor channels 302 are retained as the gate electrode layers 306 of the P-type field effect transistor, and the other gate electrode layers 306 are selectively removed.

As shown in FIG. 13, step 7-2) is performed. Electron material layers may be deposited by using a chemical vapor deposition process (CVD) or an atomic layer deposition process (ALD), and then only the gate electrode layers 406 outside the second semiconductor channels 402 are retained as the gate electrode layers 406 of the N-type field effect transistor, and the other gate electrode layers 406 are selectively removed.

The material of the gate electrode layers 406 of the N-type field effect transistor may include one of TiN, TaN, TiAl and Ti.

The material of the gate electrode layers 306 of the P-type field effect transistor may include one of TiN, TaN, TiAl and Ti.

For example, gate electrode layers 406 of the N-type field effect transistor and the gate electrode layers 306 of the P-type field effect transistor may have different materials.

As shown in FIG. 14, step 8) is performed. The P-type field effect transistor may be formed based on the first semiconductor channels 302, and the N-type field effect transistor may be formed based on the second semiconductor channels 402, in which the gate electrode layers 406 of the N-type field effect transistor may be connected with the gate electrode layers 306 of the P-type field effect transistor by a common electrode 60 to form an inverter.

The P-type field effect transistor may be composed of the first semiconductor channel 302 and the first semiconductor layers 303, the second semiconductor layers 304, the gate dielectric layer 305, and the gate electrode layers 306 sequentially wrapped all around the first semiconductor channel 302. The N-type field effect transistor may be composed of the second semiconductor channel 402 and the first semiconductor layers 403, the second semiconductor layers 404, the gate dielectric layer 405, and the gate electrode layers 406 sequentially wrapped all around the second semiconductor channel 402. The semiconductor device may include at least two N-type field effect transistors stacked upward from the substrate 101 and at least two P-type field effect transistors stacked upward from the substrate 101, and there is a gap between two adjacent N-type field effect transistors and a gap between two adjacent P-type field effect transistors. The gate electrode layers 406 of the N-type field effect transistor may be connected with the gate electrode layers 306 of the P-type field effect transistor by a common electrode 60 to form an inverter. The material of the common electrode 60 may include one of Al, W, and Cu.

As described above, the semiconductor device and the manufacturing method thereof have the following beneficial effects:

The three-dimensional stacked gate-all-around field effect transistor structure of the present invention can realize multi-layer stack of device under a unit area, effectively improve the integration level of device, and greatly improve the power of device.

The present invention has an ability to greatly improve the mobility of holes, improve the current carrying capacity of the P-type field effect transistor, and reduce the resistance and power consumption by wrapping a layer of the first semiconductor layers 303, 403 around a silicon nano channel, such as Ge, to make the first semiconductor layers 303, 403 have a band gap narrower than a band gap of the semiconductor channel to form a two-dimension hole gas in the quantum well; and then, the present invention has an ability to greatly improve the mobility of electrons, improve the current carrying capacity of the N-type field effect transistor, and reduce the resistance and power consumption by wrapping a layer of the second semiconductor layers 304, 404 around the first semiconductor layers 303, 403, such as Si, to make the second semiconductor layers 304, 404 have a band gap wider than a band gap of the first semiconductor layers 303, 403 to form a two-dimension electron gas in the quantum well.

Therefore, the present invention effectively overcomes various shortcomings in the prior art and has high industrial utilization value.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A semiconductor device, comprises:
a subtract;
a semiconductor channel, suspended above the subtract;
a first semiconductor layer, wrapped all around the semiconductor channel;
a second semiconductor layer, wrapped all around the first semiconductor layer;
a gate dielectric layer, wrapped all around the second semiconductor layer; and
a gate electrode layer, wrapped all around the gate dielectric layer, wherein the first semiconductor layer has a band gap narrower than a band gap of the semiconductor channel.

2. The semiconductor device according to claim 1, wherein the first semiconductor layer comprises a quantum well layer, and a two-dimensional hole gas is formed in the quantum well layer.

3. The semiconductor device according to claim 2, wherein the material of the semiconductor channel includes Si, and the material of the first semiconductor layer includes Ge.

4. The semiconductor device according to claim 3, wherein the material of the first semiconductor layer includes one of Ge and SiGe having compressive strain, and the content of Ge in SiGe is at least 50%.

5. The semiconductor device according to claim 1, wherein the second semiconductor layer has a band gap wider than a band gap of the first semiconductor and narrower than a band gap of the semiconductor channel.

6. The semiconductor device according to claim 5, wherein the second semiconductor layer comprises a quantum well layer, and a two-dimensional electron gas is formed in the quantum well layer.

7. The semiconductor device according to claim 6, wherein the material of the first semiconductor layer includes Ge, and the material of the second semiconductor layer includes Si.

8. The semiconductor device according to claim 7, wherein the material of the first semiconductor layer includes one of Ge and SiGe having compressive strain, in which the content of Ge in SiGe is at least 50%, and the material of the second semiconductor layer includes Si having compressive strain.

9. The semiconductor device according to claim 1, wherein the semiconductor channel is rounded to have a cross-sectional shape of a rounded rectangle.

10. The semiconductor device according to claim 9, wherein the semiconductor device includes at least two of the semiconductor channels, a P-type field effect transistor is formed based on a first semiconductor channel, an N-type field effect transistor is formed based on a second semiconductor channel, and a gate electrode layer of the N-type field effect transistor is connected with a gate electrode layer of the P-type field effect transistor by a common electrode to form an inverter.

11. The semiconductor device according to claim 10, wherein the semiconductor device includes at least two N-type field effect transistors stacked upward from the substrate and at least two P-type field effect transistors stacked upward from the substrate, and there is a gap between two adjacent N-type field effect transistors and a gap between two adjacent P-type field effect transistors.

12. The semiconductor device according to claim 10, wherein the material of the gate electrode layer of the N-type field effect transistor includes one of TiN, TaN, TiAl, and Ti, the material of the gate electrode layer of the P-type field effect transistor includes one of TiN, TaN, TiAl, and Ti, and the material of the common electrode includes one of Al, W, and Cu.

13. A manufacturing method of the semiconductor device comprises the steps of:
1) providing a subtract with a semiconductor channel suspended above the subtract;
2) forming a first semiconductor layer wrapped all around the semiconductor channel with a band gap of the first semiconductor layer narrower than a band gap of the semiconductor channel;
3) forming a second semiconductor layer wrapped all around the first semiconductor layer;
4) forming a gate dielectric layer wrapped all around the second semiconductor layer; and
5) forming a gate electrode layer wrapped all around the gate dielectric layer.

14. The manufacturing method according to claim 13, wherein the first semiconductor layer comprises a quantum well layer, and a two-dimensional hole gas is formed in the quantum well layer.

15. The manufacturing method according to claim 13, wherein the material of the semiconductor channel includes Si, and the material of the first semiconductor layer includes Ge.

16. The manufacturing method according to claim 15, wherein the material of the first semiconductor layer includes one of Ge and SiGe having compressive strain, in which the content of Ge in SiGe is at least 50%.

17. The manufacturing method according to claim 13, wherein the second semiconductor layer has a band gap wider than a band gap of the first semiconductor and narrower than a band gap of the semiconductor channel.

18. The manufacturing method according to claim 13, wherein the second semiconductor layer comprises a quantum well layer, and a two-dimensional electron gas is formed in the quantum well layer.

19. The manufacturing method according to claim 13, wherein the material of the first semiconductor layer includes Ge, and the material of the second semiconductor layer includes Si.

20. The manufacturing method according to claim 13, wherein the material of the first semiconductor layer comprises one of Ge and SiGe having compressive strain, in which the content of Ge in SiGe is at least 50%, and the material of the second semiconductor layer includes Si having compressive strain.

21. The manufacturing method according to claim 13, wherein the step 1) comprises a step of forming at least two of the semiconductor channels on the substrate, and the method further includes steps of forming a P-type field effect transistor based on a first semiconductor channel, forming an N-type field effect transistor based on a second semiconductor channel, and depositing a common electrode after the step 5), in which the common electrode connects a gate electrode layer of the N-type field effect transistor with a gate electrode layer of the P-type field effect transistor to form an inverter.

22. The manufacturing method according to claim 13, wherein the step 1) comprises a step of forming at least two first semiconductor channels stacked upward from the substrate and at least two second semiconductor channels stacked upward from the substrate, in which there is a gap between two adjacent first semiconductor channels and a gap between two adjacent second semiconductor channels, and the method further includes steps of forming at least two P-type field effect transistors stacked upward from the substrate based on the first semiconductor channel, forming at least two N-type field effect transistors stacked upward from the substrate based on the second semiconductor channel, and depositing a common electrode after the step 5), in which the common electrode connects a gate electrode layer of the N-type field effect transistors with a gate electrode layer of the P-type field effect transistors to form an inverter.

23. The manufacturing method according to claim 13, wherein the material of the gate electrode layer of the N-type field effect transistors comprises one of TiN, TaN, TiAl, and Ti, the material of the gate electrode layer of the P-type field effect transistors includes one of TiN, TaN, TiAl, and Ti, and the material of the common electrode includes one of Al, W, and Cu.
